(19) United States
(12) Patent Application Publication
(10) Pub. No.: US 2014/0161571 A1
(43) Pub. Date: Jun. 12, 2014

(54) SUBSTRATE PROCESSING APPARATUS

(71) Applicant: TOKYO ELECTRON LIMITED, Tokyo (JP)

(72) Inventors: Keisuke HIRAIDE, Nirasaki City (JP); Yoshiki YAMADA, Sapporo City (JP)

(73) Assignee: TOKYO ELECTRON LIMITED, Tokyo (JP)

(21) Appl. No.: 14/097,825

(22) Filed: Dec. 5, 2013

(30) Foreign Application Priority Data
Dec. 12, 2012 (JP) 2012-271382

(51) Int. Cl. H01L 21/677

(52) U.S. Cl. CPC H01L 21/6773
USPC 414/217.1; 414/222.13

(57) ABSTRACT

A substrate processing apparatus having a plurality of processing modules connected to the substrate transfer chamber and including first and second processing modules configured to perform different types of processing. The apparatus also includes a substrate transfer mechanism performing a carry-in operation of an unprocessed substrate into the substrate transfer chamber, a carry-out operation and a transfer of the substrate between the modules, a dummy substrate holder configured to hold a plurality of dummy substrates, and a control part configured to perform an operation of continuously carrying the dummy substrates from the dummy substrate holder into the first processing module when a waiting time for which the first processing module waits for carry-in of the substrate exceeds a predetermined setting time.

### CROSS-REFERENCE TO RELATED APPLICATION

This application claims the benefit of Japanese Patent Application No. 2012-271382, filed on Dec. 12, 2012, in the Japan Patent Office, the disclosure of which is incorporated herein in its entirety by reference.

### TECHNICAL FIELD

The present disclosure relates to a substrate processing apparatus which processes a substrate by using a plurality of different processing modules.

### BACKGROUND

In a manufacturing process of a semiconductor device, a substrate processing apparatus such as a multi chamber or a cluster tool is used, in which different types of processing modules, for example, a film forming module for forming a film on a surface of a semiconductor wafer (hereinafter referred to as a wafer) through reaction by reaction gases, a plasma processing module for processing a film formed on a surface of the wafer using plasma, and the like, are connected to a common substrate transfer chamber.

In such a type of substrate processing apparatus, different processes can be consecutively performed on the wafers by transferring the wafers to each of processing modules in turn. In addition, only particular processing modules selected as needed may be used in processing the wafer.

In the substrate processing apparatus, the processing modules are sometimes put in a standby state for a while until next processing is restarted, after previous processing on a predetermined number of wafers is completed. In addition, in the case where only particular processing modules are selected for the wafer processing, other unselected processing modules are also put in a standby state. However, depending on the types of processing modules being used, if the waiting time for the standby state is lengthened, processing results obtained after restart of the wafer processing may deteriorate when compared to processing results before the standby state.

For example, a substrate processing apparatus including a plurality of processing modules (process chambers) has been proposed in a related art, in which dummy wafers are used in order to prevent internal atmosphere within processing modules from being changed due to an extension of unused time of the processing modules. However, in the related art, there is no description relating to the operations of processing modules in a standby state while the wafer processings are being performed using other processing modules.

### SUMMARY

Some embodiments of the present disclosure provide a substrate processing apparatus capable of processing dummy substrates and product substrates in parallel by a plurality of processing modules.

According to one embodiment of the present disclosure, provided is a substrate processing apparatus for processing a substrate transferred into a processing module via a substrate transfer chamber after being taken out from a transfer container accommodating the plurality of substrates and mounted on a container mounting part, the substrate processing apparatus including: a plurality of processing modules connected to the substrate transfer chamber and including first and second processing modules configured to perform different types of processing; a substrate transfer mechanism provided in the substrate transfer chamber and configured to perform a carry-in operation of an unprocessed substrate into the substrate transfer chamber, a carry-out operation of a process-completed substrate out of the substrate transfer chamber, and a transfer of the substrate between the plurality of processing modules; a dummy substrate holder configured to hold a plurality of dummy substrates for dummy processing; and a control part configured to perform an operation of continuously carrying the dummy substrates from the dummy substrate holder into the first processing module via the substrate transfer chamber to perform a continuous dummy process when a waiting time for which the first processing module waits for carry-in of the substrate exceeds a predetermined setting time, and perform an operation of performing processing a product substrate carried into the second processing module by the substrate transfer mechanism after being taken out from the transfer container when the transfer container accommodating the product substrate is mounted on the container mounting part, while said continuous dummy processing is parallel-performed.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plane view of a substrate processing apparatus according to an embodiment.

FIG. 2 is a block diagram illustrating an electrical configuration of the substrate processing apparatus.

FIG. 3 is a flow chart illustrating a flow of operation in creating a processing recipe and a transfer schedule.

FIG. 4 is an explanatory view illustrating a wafer transfer path in normal processing performance

FIG. 5 is an explanatory view illustrating a wafer transfer path in single plasma nitridation performance

FIG. 6 is an explanatory view illustrating a wafer transfer path in continuous dummy processing performance.

FIG. 7 is a first explanatory view illustrating a wafer transfer path when single plasma nitridation is started during performance of continuous dummy processing.

FIG. 8 is a second explanatory view illustrating a wafer transfer path when the single plasma nitridation is started.

FIG. 9 is a first explanatory view illustrating a wafer transfer path when single plasma nitridation and continuous dummy processing are performed in parallel.

FIG. 10 is a second explanatory view illustrating a wafer transfer path when single plasma nitridation and continuous dummy processing are performed in parallel.

FIG. 11 shows an example of a transfer schedule in normal processing.

FIG. 12 shows an example of a transfer schedule in single plasma nitridation.

FIG. 13 shows an example of a transfer schedule in continuous dummy processing.

FIG. 14 shows an example of a transfer schedule at the time of starting single plasma nitridation during performance of continuous dummy processing.

FIG. 15 shows an example of a transfer schedule at the time of starting continuous dummy processing during performance of single plasma nitridation.

FIG. 16 shows an example of a first transfer schedule when two processing modules are used to perform continuous dummy processing.

FIG. 17 shows an example of a second transfer schedule when two processing modules are used to perform continuous dummy processing.

FIG. 18 shows an example of a transfer schedule when normal processing is performed during performance of continuous dummy processing.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

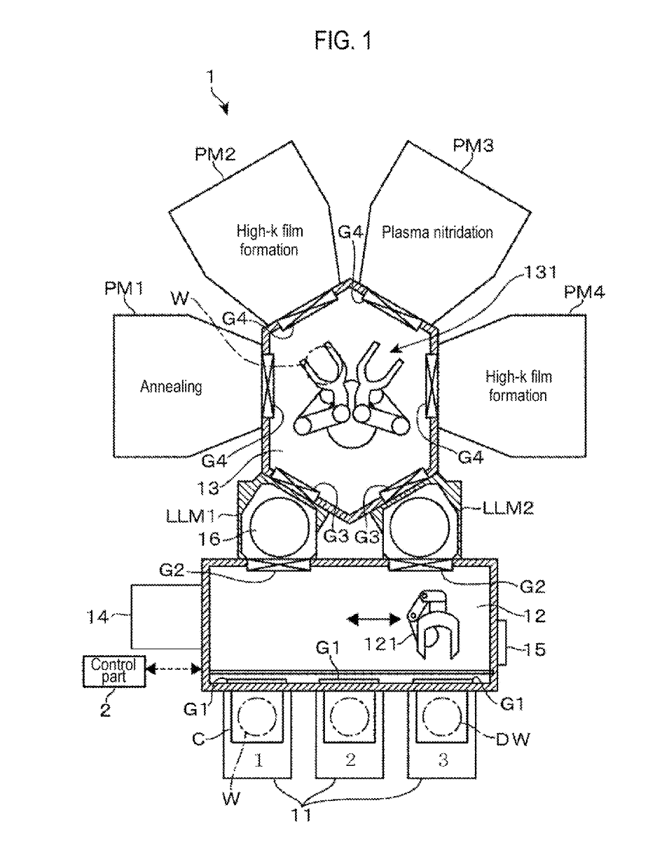

In an embodiment of the present disclosure, description is made exemplifying a substrate processing apparatus 1 including processing modules PM1 to PM4 for forming a high dielectric material film (hereinafter referred to as high-k film) used as a gate insulating film of a semiconductor device on a wafer W and performing a plasma process or an annealing process for this film. As shown in FIG. 1, the substrate processing apparatus 1 includes a carrier mounting table 11 as a container mounting part on which a carrier C (a transfer container) accommodating a predetermined number of, for example, 25 wafers W to be processed is mounted, an atmospheric transfer chamber 12 for transferring the wafers W under an atmospheric environment, which are taken out of the carrier C, load lock chambers LLM1 and LLM2 in which the wafers W stay, the load lock chambers LLM1 and LLM2 switching internal pressure between the atmospheric environment and a preliminary vacuum environment for the stay of the Wafer W, a vacuum transfer chamber 13 for transferring the wafer W under a vacuum environment, and processing modules PM1 to PM4 for processing the wafer W. These components are arranged in order of the atmospheric transfer chamber 12, the load lock chambers LLM1 and LLM2, the vacuum transfer chamber 13 and the processing modules PM1 and PM4 in a carrying-in direction of the wafer W. Adjacent components are air-tightly interconnected via a door G1, a door valve G2 and gate valves G3 and G4.

Provided within the atmospheric transfer chamber 12 is a transfer arm 121 which can be rotated, expanded/contracted, elevated and horizontally moved to take and transfer the wafers W one by one from the carrier C. Provided on a side of the atmospheric transfer chamber 12 is an alignment chamber 14 containing an orienter for aligning the wafers W.

The load lock chambers LLM1 and LLM2 are arranged in a left-right direction, when viewed from the carrier mounting table 11, to connect the atmospheric transfer chamber 12 and the vacuum transfer chamber 13. Each of the load lock chambers LLM1 and LLM2 has a mounting table 16 on which the carried-in wafer W is mounted, a vacuum pump and a leak valve (both not shown) connected thereto to switch the internal pressure of each of the load lock chambers LLM1 and LLM2 between the atmospheric environment and the vacuum environment.

The vacuum transfer chamber 13 has, for example, a hexagonal shape in a plane view and its interior has a vacuum environment. Two frontal sides of the vacuum transfer chamber 13 are respectively connected with the above-described load lock chambers LLM1 and LLM2 and the remaining four sides thereof are respectively connected with the processing modules PM1 to PM4.

Provided within the vacuum transfer chamber 13 is a transfer arm 131 which can be rotated and expanded/contracted to transfer the wafers W between the load lock chambers LLM1 and LLM2 and the processing modules PM1 to PM4. In addition, the vacuum transfer chamber 13 is connected with a vacuum pump (not shown) for keeping the inside of the vacuum transfer chamber 13 at a vacuum environment.

In this example, the transfer arms 121 and 131 correspond to a substrate transfer mechanism and the vacuum transfer chamber 13 corresponds to a substrate transfer chamber.

The processing modules PM1 to PM4 perform different types of processes on the wafers W. In this example, the processing modules PM2 and PM4 are configured as film forming modules for forming a high-k film by reaction of reaction gases on a surface of the wafer W placed within a processing container under the vacuum environment. The processing modules PM2 and PM4 may form the same kind of high-k film. In this example, the processing modules PM2 and PM4 form a HfSiO film as a high-k film by means of thermal CVD (Chemical Vapor Deposition) through reactions of silicon-containing TEOS (tetraethyl ortho silicate), HTB (hafnium tertiary butoxide) as a hafnium-containing organometallic material, and an oxidation gas (for example, O₂).

In addition, the processing module PM3 performs plasma nitridation for the high-k film formed by the processing modules PM2 and PM4 by plasma using RLSA (Radial Line Slot Antenna). For example, the processing module PM3 uses an Ar gas as a noble gas for generating plasma and uses a N₂ gas as a nitriding gas. The plasma nitridation is performed to prevent HfSiO from being separated into metal oxide and silicon oxide and maintain a state of metal silicate stably under a high temperature.

Subsequently, the processing module PM1 performs an annealing process (PNA; Post Nitridation Anneal) by heat for the high-k film nitrided in the processing module PM3. A N₂ gas and an O₂ gas are used as gases forming an atmosphere under which the annealing process is performed. The annealing process densities the high-k film by high temperature treatment in order to prevent nitrogen introduced by the plasma nitridation from escaping from the high-k film.

The above-described processes performed in the processing modules PM1 to PM4 are only an example of a combination of processes used in an embodiment of the present disclosure. Therefore, the number of processing modules and types, combination and order of processes in the substrate processing apparatus 1 to which the present disclosure is applied are not limited to those described herein. For example, in addition to the above-described processing modules for the film formation, the plasma nitridation and the annealing, the apparatus 1 may further include processing modules for performing an etching process for etching a film on the surface of the wafer W by using an etching gas, a plasma ashing process for decomposing and removing a resist film from the surface of the wafer W after the etching process and so on.

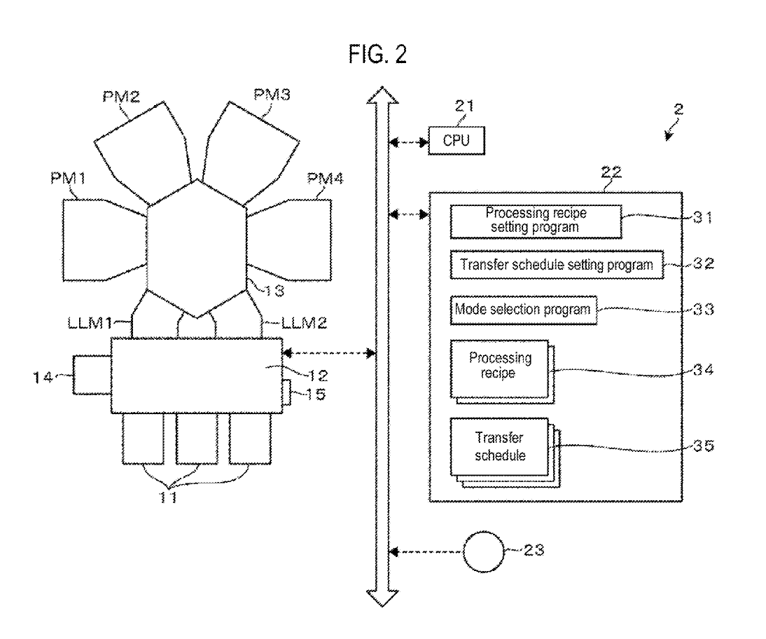

As shown in FIGS. 1 and 2, the substrate processing apparatus 1 further includes a control part 2. The control part 2 is implemented with a computer including a CPU 21 and a storage unit 22 storing a program in which a group of steps (instructions) for outputting control signals to execute the above-described operations of processing the wafer W are contained. This program is stored in a storage medium such as a hard disk, a compact disk, a magneto-optical disk, a memory card or the like and is installed from the storage medium into the storage unit 22. The program and setting values stored in the storage unit 22 can be edited through a touch panel display 15 provided on the side wall of the atmospheric transfer chamber 12.

In this example, in addition to performing the various processes (film formation→plasma Nitridation→annealing; hereinafter collectively referred to as “normal process”) for the wafer W using all of the processing modules PM1 to PM4 provided within the substrate processing apparatus 1, as described above, the substrate processing apparatus 1 may selectively use only particular processing modules for processing the wafer W. As an example of the latter, after a wafer W on which a metal film such as titanium or the like is formed by other film forming apparatuses is carried into the processing module PM3, plasma nitridation may be performed to form a metal nitride film on the surface of the wafer W (hereinafter referred to as “single plasma nitridation”).

In some cases, in the substrate processing apparatus 1, the processing modules PM1 to PM4 may be put in a standby state after their normal processes being performed end, and then the next process (the normal process or the single plasma nitridation) may be started after the lapse of a certain period of time. In these cases, as described above, if the waiting time of the processing modules PM2 and PM4 for the high-k film formation is lengthened, the result of film formation may deteriorate, e.g., decrease of the relative dielectric constant of the high-k film after restart of the process than that before the waiting. In addition, the same problem may occur in the processing modules PM2 and PM4 for forming the film which are put in the standby state during the above-described single plasma nitridation.

Thus, in order to obtain a stable result of film formation, the substrate processing apparatus 1 includes a function of processing a dummy wafer DW (hereinafter referred to as “continuous dummy processing”) in the processing modules PM2 and PM4 for film formation in the standby state. The processing of the dummy wafer DW may be also performed in the standby-state processing modules (PM1 to PM4) before restarting the process (hereinafter referred to as “lot stabilizing dummy processing”).

Details of these functions will be described below.

As shown in FIG. 2, the storage unit 22 of the control part 2 stores a processing recipe 34 including the programs and setting values related to operations of the processing modules PM1 to PM4, and a transfer schedule 35 including information related to modules at transfer destinations (the load lock chambers LLM1 and LLM2 and the processing modules PM1 to PM4) to which the product wafers W and the dummy wafers DW are transferred. In addition, the storage unit 22 stores a processing recipe setting program 31 through which the operator, e.g., sets or changes the setting values of the processing recipe 34, a transfer schedule setting program 32 through which the operator changes a setting of the transfer schedule 35 or prepares transfer schedules 35 varying depending on the running processing modules PM1 to PM4, and a mode selection program 33 through which the operator selects a mode to set performance conditions for the continuous dummy processing. For the setting and change described above, the operator can use, e.g., the touch panel display 15.

In addition, the control part 2 includes a timer 23 so that it can determine whether or not the elapsed waiting time of the processing modules PM2 and PM4 is a set amount of time which will be described later.

Regarding the process for product wafers W, the processing recipe setting program 31 receives a setting value on process selection, e.g., the normal process or the single plasma nitridation and a setting value on processing conditions of the processing modules PM1 to PM4 used for the selected process, and performs preparation of the processing recipe 34 for processing the product wafers W or change of the setting values. Herein, let's suppose that the normal process is a main mode while the single plasma nitridation is a sub-mode. In this embodiment, the control part 2, which serves to select one of these modes based on the processing recipe setting program 31, also includes a function as a selection part.

With regard to the process for the dummy wafer DW, the processing recipe setting program 31 receives a setting value meaning selection of the continuous dummy processing in the processing modules PM2 and PM4, and prepares the processing recipe 34 for the continuous dummy processing or change of setting values. In addition, in this example, setting values for the lot stabilizing dummy processing are set in the processing recipe 34 for the product wafer W.

Herein, the same process as that in the high-k film forming process for producing the product wafers W is performed in the continuous dummy processing and the lot stabilizing dummy processing in the substrate processing apparatus 1 of this example. However, as long as the quality of the high-k film formed in the processing modules PM2 and PM4 can be maintained at a target value, the processing time of the dummy wafer DW in the dummy processing may be shortened or a flow rate of reaction gas may be reduced.

With regard to the processing for the dummy wafer DW, the transfer schedule setting program 32 receives a setting of a setting time specifying a timing of the start of the continuous dummy processing and a setting of modules at transfer destinations. The setting time is stored along with, for example, the transfer schedule 35 for the dummy wafer DW. The control part 2 compares this setting time with the waiting time of the processing modules PM2 and PM4 by the timer 23. If the waiting time exceeds the setting time, the processing of the dummy wafer DW is started based on the transfer schedule 35 and the processing recipe 34 for the continuous dummy processing. In this example, a transfer destination of the dummy wafer DW in the lot stabilizing dummy processing is set in the transfer schedule 35 for the product wafer W.

When the continuous dummy processing is started after the setting time lapses, the mode selection program 33 receives information on a mode selection selecting a mode of performing the continuous dummy processing and the single plasma nitridation in parallel or a mode of performing only the single plasma nitridation without performing the parallel processing. The control part 2, which selects one of these modes based on the mode selection program 33, includes a function as a selection part in this embodiment. Details of the function of performing the continuous dummy processing and the single plasma nitridation in parallel will be described later.

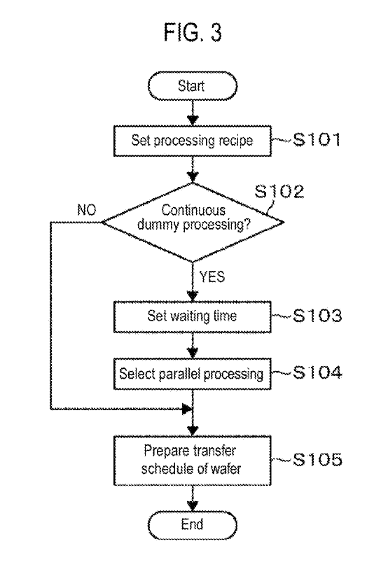

An operation of the substrate processing apparatus 1 having a configuration described above will now be described with reference to FIGS. 3 to 18. In these figures, the film forming process, the plasma nitridation and the annealing process for the high-k film are denoted by “film formation,” “PNT” and “PNA,” respectively.

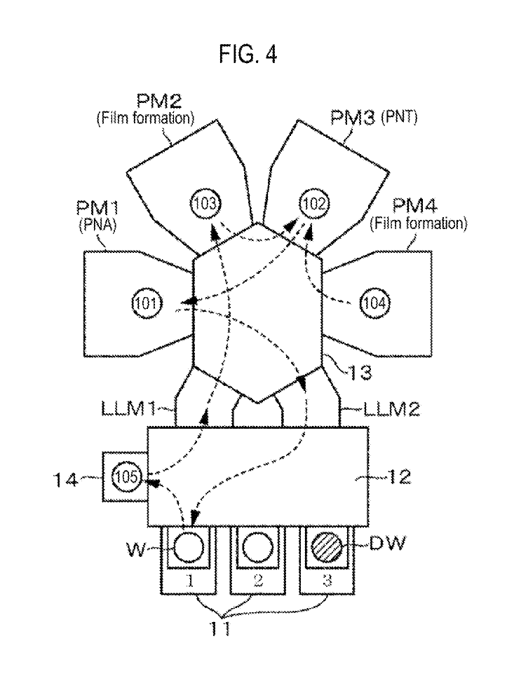

Here, the three-digit numbers shown in FIGS. 4 to 18 are numbers that identify the wafers W accommodated in the processing modules PM1 to PM4. The leftmost digit in the three-digit numbers is the identification number of the carrier mounting table 11 on which the carrier C accommodating wafer W in question is mounted. As shown in FIGS. 4 to 10, the carrier mounting tables 11 are denoted by identification numbers “1”, “2” and “3” in the order from the left when viewed from the front side. Further, the remaining two-digits in the three-digit number correspond to slots in the carrier C in which wafer W in question is held. Identification numbers of “01” to “25” are given to the slots in turn from the top.

Accordingly, an identification number “101” represents “a wafer W positioned in the No. 01 (uppermost) slot in the carrier C mounted on the No. 1 carrier mounting table 11” and an identification number “325” represents “a wafer W positioned in the No. 25 (lowermost) slot in the carrier C mounted on the No. 3 carrier mounting table 11”. In the examples shown in FIGS. 4 to 10, the carrier mounting tables 11 denoted by identification numbers “1” and “2” are ones on which the carrier C accommodating the product wafers W is mounted and the carrier mounting table 11 denoted by an identification number “3” is one on which the carrier C accommodating the dummy wafers DW is mounted. The carrier C mounted on the No. 3 carrier mounting table 11 corresponds to a dummy substrate holder in this example.

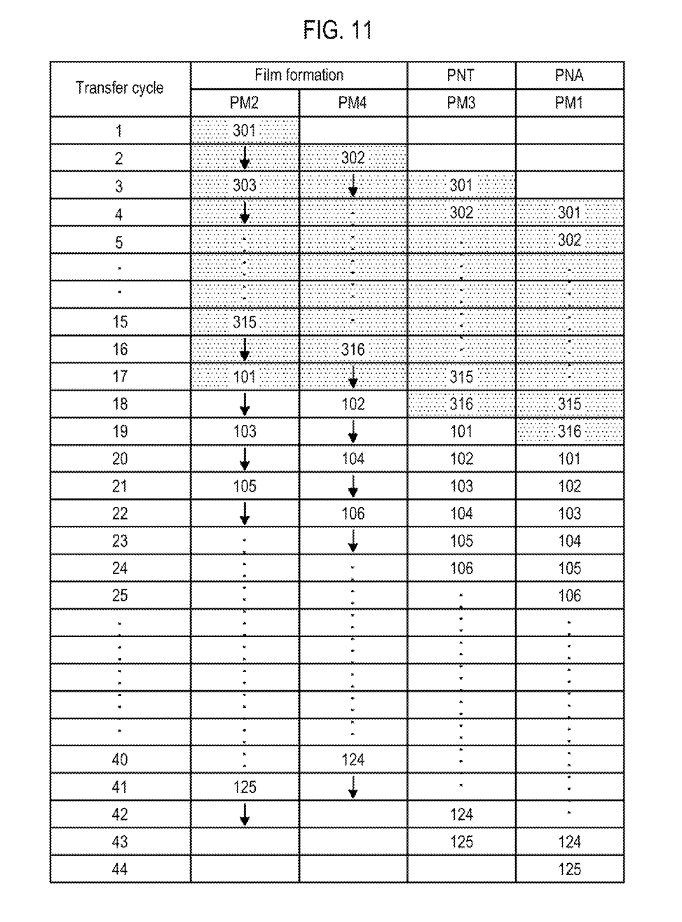

Herein, it is assumed that times required for the switching between the atmospheric environment and the vacuum environment in the load lock chambers LLM1 and LLM2 and for the transfer arms 121 and 131 to transfer the wafers W and DW are sufficiently shorter than the processing time for the product wafer W and the dummy wafer DW in the processing modules PM1 to PM4. Accordingly, in the transfer schedule shown in FIGS. 11 to 18, the time for operation of this transfer system (the load lock chambers LLM1 and LLM2 and the transfer arms 121 and 131) provides no limitation to the transfer of the wafers W and DW.

Before the start of the substrate processing apparatus 1, the processing recipe 34 and the transfer schedule 35 are first set by the operator and received through the touch panel display 15. As shown in FIG. 3, settings of the processing recipe 34 for each of the product wafer W and the dummy wafer DW (Step S101) are received. If the set processing recipe 34 is not related to the continuous dummy processing (“NO” in Step S102), after the setting of the processing recipe 34, the transfer schedule 35 for the product wafer W is prepared (Step S105) and is then stored in the storage unit (22) (END).

On the other hand, if the set processing recipe 34 is related to the continuous dummy processing (“YES” in Step S102), the waiting time is further set (Step S103), the selection of whether to perform the continuous dummy processing in parallel to the single plasma nitridation is received (Step S104), and the transfer schedule 35 for the dummy wafer DW in the continuous dummy processing is prepared (Step S105) and is then stored in the storage unit 22 (END).

In Step S102, whether the setting is for the continuous dummy processing may be switched through a button or the like displayed on a screen of the touch panel display 15.

Processing for the product wafer W and the dummy wafer DW is performed based on the processing recipe 34 and the transfer schedule 35 prepared as described above.

First, the entire operation of the substrate processing apparatus 1 will be described with an example of performing the normal processing for the product wafer W. For example, as shown in FIG. 4, when carrier C accommodating product wafers W is mounted on a “1” carrier mounting table 11, the wafers W of the carrier C are taken in turn from the top slot by the transfer arm 121. Wafer W held by the transfer arm 121 is aligned in the alignment chamber 14 while it is being transferred throughout the atmospheric transfer chamber 12, and is then delivered to one of the left and right load lock chambers LLM1 and LLM2.

When the preliminary vacuum environment is made within the load lock chamber LLM1 and LLM2, the wafer W is taken out and transferred to the vacuum transfer chamber 13 by the transfer arm 131. Thereafter, while the wafer W is transferred between the vacuum transfer chamber 13 and the processing modules PM1 to PM4, processes are performed on the wafer W in an order of the high-k film formation (processing modules PM2 and PM4) the plasma nitridation (processing module PM3) the annealing process (processing module PM1). The processed wafer W is carried out through the reverse path (excluding the alignment chamber 14) to the carrying-in path and is finally accommodated in the original carrier C.

In the explanatory views of FIGS. 4 to 10, to avoid intricate arrows indicating transfer routes, an example is illustrated in which one load lock chamber LLM1 is only operated for carrying-in and the other load lock chamber LLM2 is for carrying-out; however, actually, both of the load lock chambers LLM1 and LLM2 are used for carrying-in and carrying-out.

If the processing for the wafer W in the processing modules PM1 to PM4 is the one being performed at the start of the substrate processing apparatus 1 or the one being performed after the standby state of the processing modules PM1 to PM4, the lot stabilizing dummy processing using the dummy wafer DW is performed prior to the processing of the product wafer W (see FIG. 11). The lot stabilizing dummy processing is performed in the same manner as the operation for the product wafer W except that the dummy wafers DW are taken out from the carrier C mounted on the “3” carrier mounting table 11 and subject to the processing in the processing modules PM1 to PM4.

In the figures showing transfer schedules, the processing modules PM1 to PM4 into which the dummy wafer DW for the lot stabilizing dummy processing is carried are hatched with dots (see FIGS. 11, 12, 14 and 18).

Referring to the transfer path of the dummy wafer DW based on the transfer schedule shown in FIG. 11, the “301” dummy wafer DW is carried into one processing module PM2 at transfer cycle 1 for the film formation. The “302” dummy wafer DW is carried into the other processing module PM4 at the next transfer cycle 2 for film formation. At this time, the film formation on the “301” dummy wafer DW continues in the processing module PM2.

Subsequently, after completion of the film formation in the processing module PM2, the “301” dummy wafer DW is carried into the processing module PM3 for the plasma nitridation at transfer cycle 3 and then the “303” dummy wafer DW is carried into the processing module PM2. In this manner, in this example, dummy wafers DW are alternately carried into the two processing modules PM2 and PM4 (this can be equally applied to the product wafers W).

The dummy wafer DW carried into the processing module PM3 and subjected to the plasma-nitridation is carried into the processing module PM1 for the PNA at the next transfer cycle 4, and then carried into the original carrier C at the next transfer cycle 5.

In the lot stabilizing dummy processing, after the total of 16 dummy wafers DW (8 dummy wafers DW in one processing module PM2 or PM4) are processed, processing objects are switched and the processing for the product wafers W is started (after transfer cycle 17 in FIG. 11).

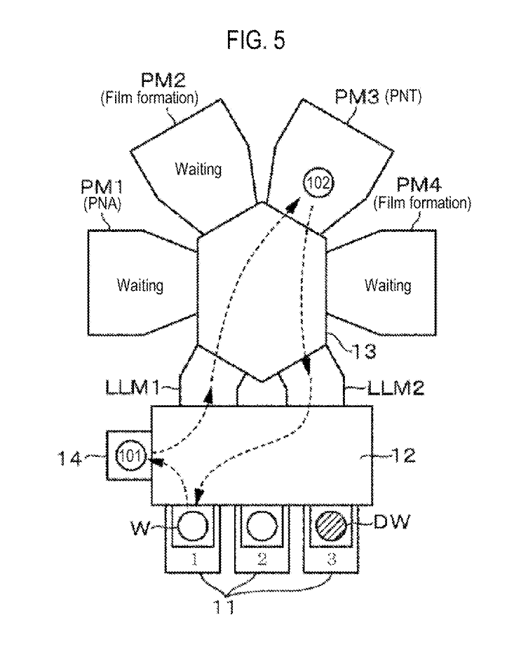

Subsequently, FIG. 5 shows a transfer path of the product wafer W in the single plasma nitridation. In the single plasma nitridation, a product wafer W taken out from a carrier C is aligned in the alignment chamber 14 and directly carried into the processing module PM3. In here, it is subjected to plasma nitridation and then carried into the original carrier C. At this time, the other processing modules PM1, PM2 and PM4 are put under the standby state.

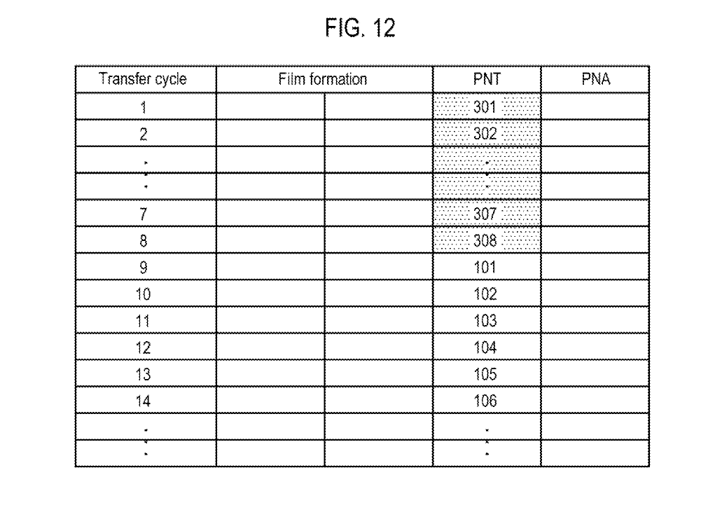

As shown in FIG. 12, even for the single plasma nitridation, the lot stabilizing dummy processing using dummy wafers DW is performed at the start of the substrate processing apparatus or after the processing module PM3 is in the waiting state.

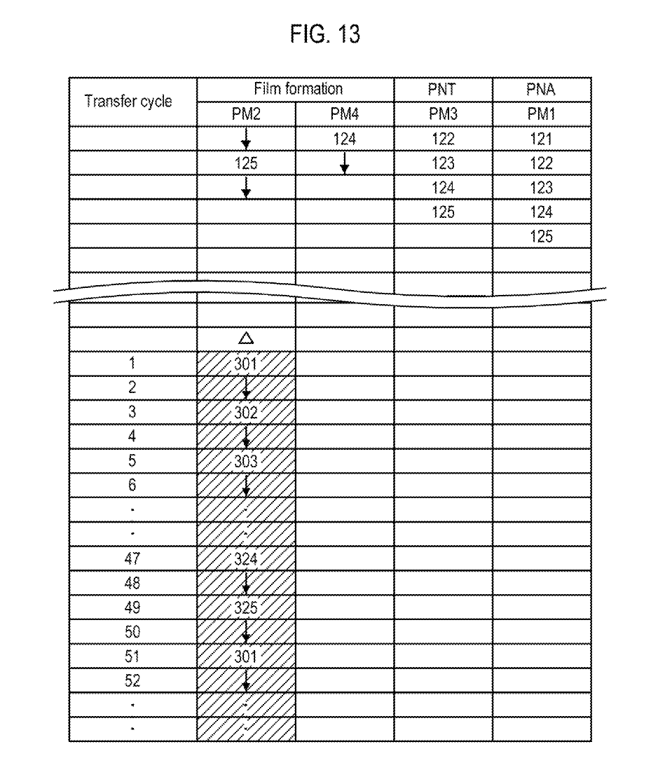

The substrate processing apparatus 1, which is capable of switching between the normal processing and the single plasma nitridation as described above, when, e.g., the processing recipe 34 for the continuous dummy processing is selected, starts the continuous dummy processing when the waiting time of the processing modules PM2 and PM4 for film formation exceeds a predetermined setting time. For example, FIG. 13 shows a case where the processing modules PM1 to PM4 are in the standby state, not starting the process for the next product wafer W after the completion of the normal processing using the processing modules PM1 to PM4.

When the setting is made such that the continuous dummy processing is performed in case the waiting time exceeds the setting time, the control part 2 monitors the waiting time after the processing module PM2 is put under the standby state.

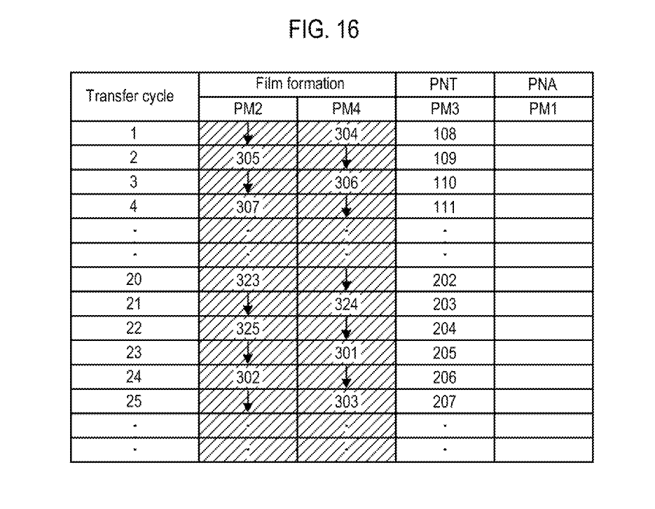

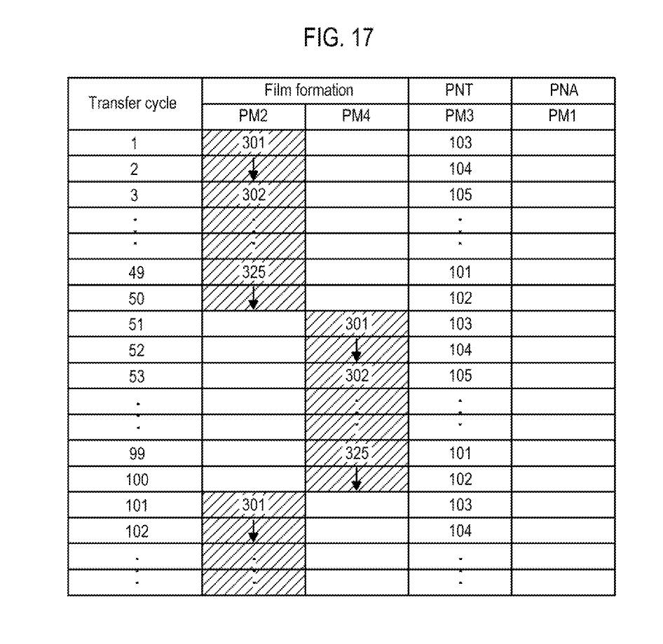

For convenience of description, the transfer schedules of FIGS. 13 to 15 illustrate an example in which the continuous dummy processing is performed only in one processing module PM2. It should be, however, understood that the continuous dummy processing may be performed in both of the processing modules PM2 and PM4, as shown in FIGS. 16 and 17 which will be described later.

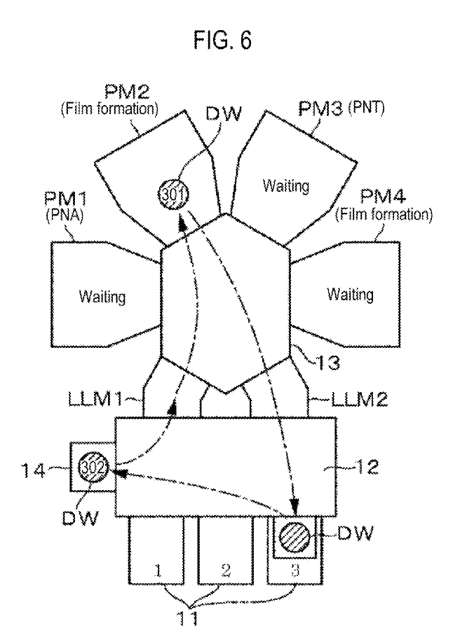

Thus, when the waiting time of the processing module PM2 exceeds the setting time (for example, 3 hours) (this is indicated by a triangle in the transfer schedule of FIG. 13, which is equally applied to the transfer schedules in the remaining figures), the dummy wafer DW is taken out from the carrier C mounted on the “3” carrier mounting table 11 in turn, beginning with the dummy wafer DW of upper side slots and is carried into the processing module PM2 where the continuous dummy processing is performed (see FIG. 6). In the processing module PM2, the same film forming process as that for the product wafer W is performed on the dummy wafer DW based on the setting of the processing recipe 34 for the continuous dummy processing.

The above-described operation steps correspond to a “performing continuous dummy processing for each dummy substrate” set forth in the claims. In the figures showing transfer schedules, the processing modules PM1 to PM4 into which the dummy wafer DW for the continuous dummy processing is carried are hatched with diagonal lines (see FIGS. 13 to 18).

Thus, when the processing for 25 dummy wafers DW in the carrier C is completed and all of the dummy wafers DW are accommodated back into the carrier C, dummy wafer DW is again taken out from the slots, beginning with the dummy wafer DW in a first slot, and the continuous dummy processing continues (transfer cycle 51 in FIG. 13). With regard to a period of time for which the continuous dummy processing is performed, for example, the continuous dummy processing may be continued for the dummy wafers DW in the carrier C by the predetermined number of repetitions. After that, the continuous dummy processing is stopped and the processing module PM2 may be in the standby state until the setting time elapses again. In addition, once the continuous dummy processing is started, the continuous dummy processing may be repeatedly performed until a separately-set limitation such as an upper limit of the number of repetitions the dummy wafer DW is used while waiting for the product wafer W to be carried-in processed in the processing module PM2.

Herein, the substrate processing apparatus 1 of this example can perform the plasma nitridation for the product wafer W in parallel to the continuous dummy processing. In this point of view, the processing modules PM2 and PM4 where the continuous dummy processing is performed correspond to a first processing module in this example while the processing module PM3 where the plasma nitridation for the product wafer W is performed corresponds to a second processing module.

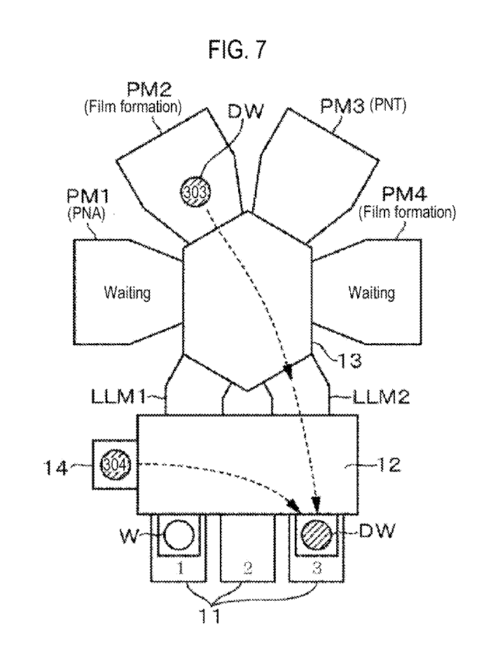

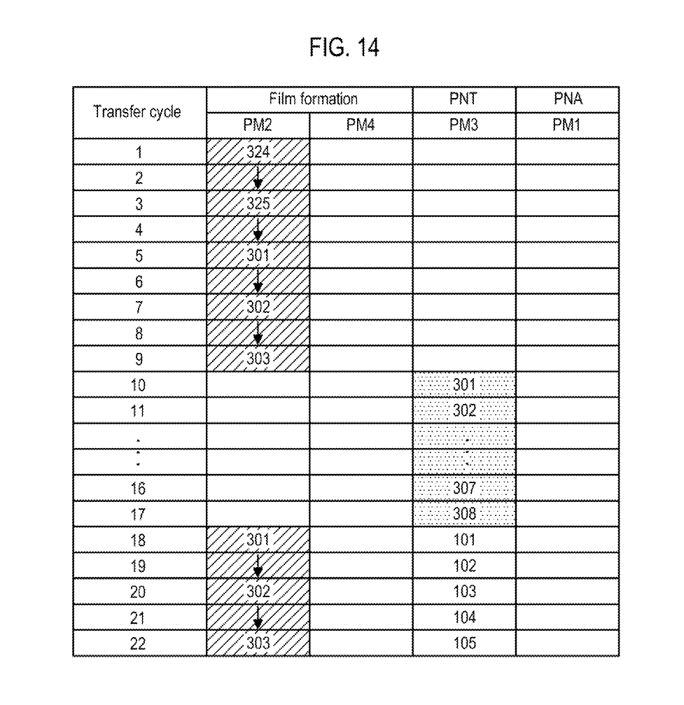

For example, FIGS. 7 to 10 and 14 show a case where the single plasma nitridation is started while the continuous dummy processing is performed in the processing module PM2. As shown in FIG. 7 and transfer cycle 9 of FIG. 14, it is assumed that the carrier C accommodating the product wafers W to be subjected to the single plasma nitridation is being mounted on the “1” carrier mounting table 11 while the “303” dummy wafer DW is processed in the processing module PM2. Then, the continuous dummy processing is stopped and the dummy wafer DW provided into the substrate processing apparatus 1 from the carrier C on the “3” carrier mounting table 11 (hereinafter abbreviated as a “3” carrier C for the purpose of simplicity) is collected in the original carrier C.

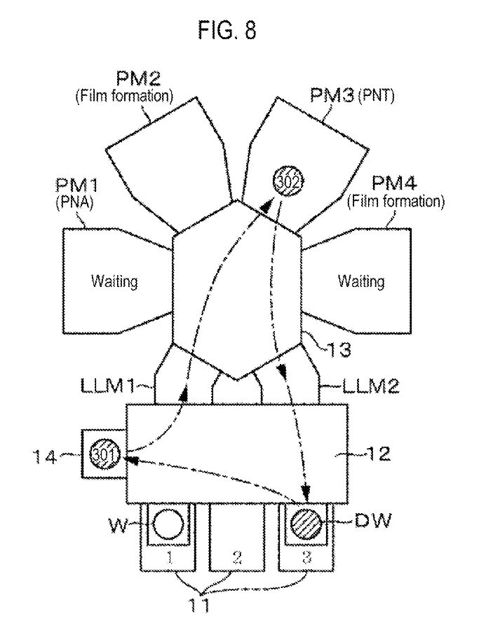

As shown in FIG. 8 and transfer cycle 10 of FIG. 14, the dummy wafer DW collected in the “3” carrier C after the continuous dummy processing is stopped is used for the lot stabilizing dummy processing in the processing module PM3 where the plasma nitridation is performed. The configuration, as described above, in which the dummy wafer DW provided into the substrate processing apparatus 1 is collected and then the lot stabilizing dummy processing is started with the uppermost “301” dummy wafer DW, makes it easier to manage the number of times of performing the continuous dummy processing and the lot stabilizing dummy processing by the lot unit with, for example, 25 dummy wafers DW as one set.

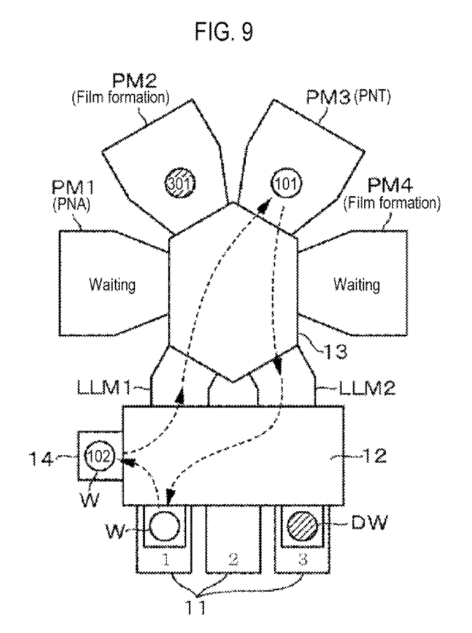

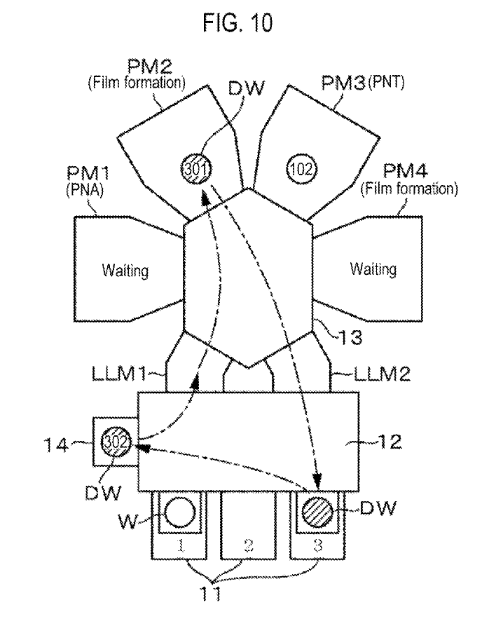

When the lot stabilizing dummy processing in the processing module PM3 is completed, the “101” product wafer W is carried from the “1” carrier C into the processing module PM3 for the plasma nitridation, as represented with transfer cycle 18 and the subsequent cycles in FIG. 14. On the other hand, the “301” dummy wafer DW is again carried from the “3” carrier C into the processing module PM2 to restart the continuous dummy processing. The transfer of the product wafers W and the dummy wafers DW to the processing modules PM2 and PM3 is made in such a way that a product wafer W or a dummy wafer DW for one of the processing modules PM2 or PM3, is taken out from the “1” or “3” carrier C and transferred to the processing module PM2 or PM3 that will be finished processing first, as shown in FIGS. 9 and 10. These operations correspond to “carrying a product substrate into a second processing module and performing substrate processing and the continuous dummy processing in parallel.”

If the mode of performing the continuous dummy processing and the single plasma nitridation in parallel is not selected, only the single plasma nitridation is performed without the restart of the continuous dummy processing.

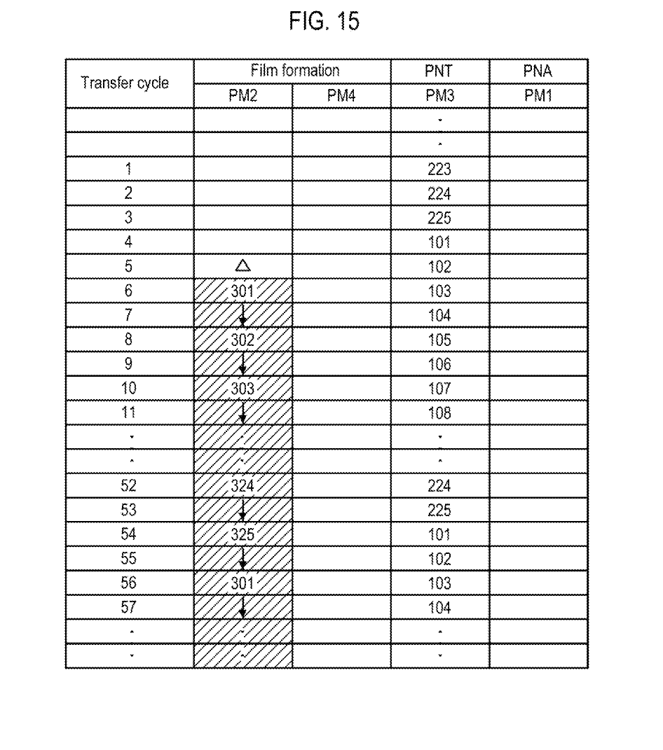

Subsequently, FIG. 15 shows a case where the continuous dummy processing is started while the single plasma nitridation is performed in the processing module PM3. Since the lot stabilizing dummy processing is not performed at the start of the continuous dummy processing, when the waiting time exceeds the setting time, the “301” dummy wafer DW is carried from the “3” carrier C into the processing module PM2 to start the continuous dummy processing. Then, as described above with reference to FIGS. 9 and 10, the wafers W and DW are carried into the processing modules PM2 and PM3 one by one and the single plasma nitridation and the continuous dummy processing are performed in parallel. On the other hand, if the mode of performing the continuous dummy processing and the single plasma nitridation in parallel is not selected, the continuous dummy processing is not started even when the setting time elapses.

Herein, as described above, the continuous dummy processing is not limited to only the processing in the processing module PM2 but may be performed in both of the film forming processing modules PM2 and PM4 provided in the substrate processing apparatus 1. For example, in the example shown in FIG. 16, by performing the single plasma nitridation in parallel with the continuous dummy processing performed in such a way that the dummy wafer DW is alternately carried into these two processing modules PM2 and PM4, deterioration of the result of the processing due to an extension of the waiting time of the processing modules PM2 and PM4 is reduced.

On the other hand, in the example shown in FIG. 17, after the continuous dummy processing using 25 dummy wafers DW is performed in the processing module PM2, the processing module in which the continuous dummy processing will be performed is switched to the processing module PM4. Since the continuous dummy processing is switched between the processing modules PM2 and PM4, e.g., using one lot as a unit, in the parallel performance of the continuous dummy processing and the single plasma nitridation, a load of the transfer system is reduced to suppress a problem occurring in the transfer of the wafers W and DW.

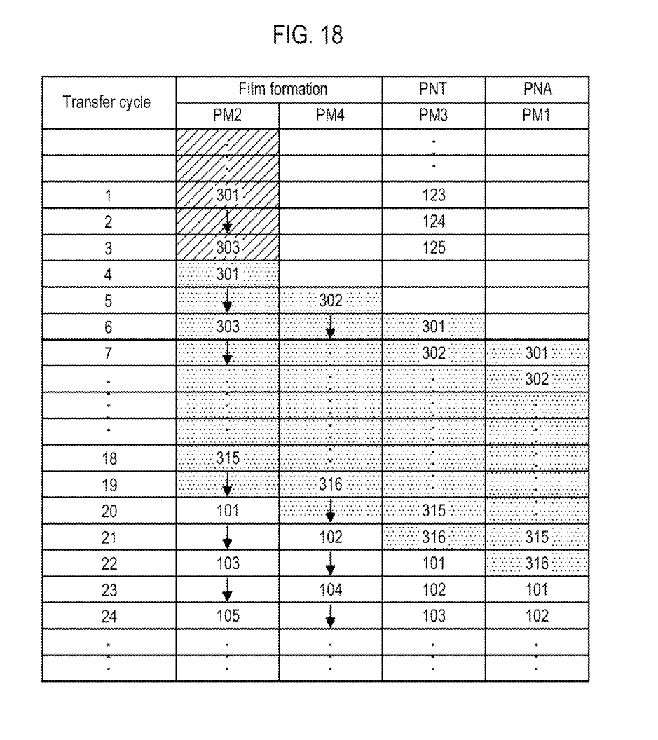

Finally, FIG. 18 shows an example of a transfer schedule in a case where the normal processing is started after the continuous dummy processing and the single plasma nitridation are performed in parallel with each other in the processing module PM2 and the processing module PM3, respectively. In this example, the dummy wafer DW provided into the substrate processing apparatus 1 is collected at the timing when the carrier C is mounted in the “1” carrier mounting table 11, and then the collected dummy wafer DW is used to perform the lot stabilizing dummy processing for the processing modules PM1 to PM4.

The substrate processing apparatus 1 according to this embodiment has the following advantages. While the continuous dummy processing is performed on the dummy wafers DW by continuously transferring them into the film forming processing modules PM2 and PM4 (the first processing module), the single plasma nitridation can be performed on the product wafers W carried into the plasma nitridation processing module PM3 (the second processing module). This can result in improvement of workability of the substrate processing apparatus 1 due to the parallel performance of the continuous dummy processing and the single plasma nitridation.

The type of the processes performed in the processing module (the first processing module) in which the continuous dummy processing is performed and in the processing module (the second processing module) in which the plasma nitridation is performed in parallel to the continuous dummy processing, the number of processing modules and the number of wafers W and DW accommodated in the carrier C are not limited to the above-described examples. A processing module for performing plasma processing, etching processing, ashing processing or the like may be selected as the first processing module and a processing module for performing film forming processing may be selected as the second processing module.

In addition, if the processing modules PM2 and PM4 for film formation are selected as the first processing module, the type of film formation to be performed is not limited to the formation of the high-k film. For example, the processing modules PM2 and PM4 may be film forming modules for forming a metal film such as, for example, Ti, Ru, Al, Mn, Co, Cu, Zn, Zr, No, Hf, W or the like, or a metal compound film such as a nitride film thereof, an oxide film thereof or the like.

In addition, the dummy substrate holder accommodating the dummy wafers DW is not limited to the carrier C mounted on the carrier mounting table 11. For example, as a dummy substrate holder, a retaining chamber accommodating therein dummy wafers DW may be provided in a side wall of the atmospheric transfer chamber 12.

In addition, the types of processing modules are not limited to those performing the processing under a vacuum atmosphere. For example, the present disclosure may be applied to a heating module for heating a wafer W under the atmospheric environment, a coating module or developing module for coating a resist solution or a development solution on a front surface of a wafer W, a cleaning module for performing a cleaning process using a cleaning solution supplied onto a front or rear surface of a wafer W, etc. In these cases, a transfer mechanism of a wafer W may not be provided in a vacuum transfer chamber.

The type of substrate to be processed in the substrate processing apparatus to which the present disclosure is applied is not limited to the wafer W but may be rectangular substrates used for, for example, manufacturing flat panels.

According to embodiments of the present disclosure, it is possible to improve workability of a substrate processing apparatus by performing both continuous dummy processing on dummy substrates consecutively carried into a first processing module and substrate processing on product substrates carried into a second processing module.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for processing a substrate transferred into a processing module via a substrate transfer chamber after being taken out from a transfer container accommodating the plurality of substrates and mounted on a container mounting part, the substrate processing apparatus comprising:
a plurality of processing modules connected to the substrate transfer chamber and including first and second processing modules configured to perform different types of processing;
a substrate transfer mechanism provided in the substrate transfer chamber and configured to perform a carry-in operation of an unprocessed substrate into the substrate transfer chamber, a carry-out operation of a process-completed substrate out of the substrate transfer chamber, and a transfer of the substrate between the plurality of processing modules;
a dummy substrate holder configured to hold a plurality of dummy substrates for dummy processing; and
a control part configured to perform an operation of continuously carrying the dummy substrates from the dummy substrate holder into the first processing module via the substrate transfer chamber to perform a continuous dummy process when a waiting time for which the first processing module waits for carry-in of the substrate exceeds a predetermined setting time, and perform an operation of performing processing a product substrate carried into the second processing module by the substrate transfer mechanism after being taken out from the transfer container when the transfer container accommodating the product substrate is mounted on the container mounting part, while said continuous dummy processing is parallel-performed.

2. The substrate processing apparatus of claim 1, wherein the control part is configured to perform an operation of performing dummy processing in the second processing module using the dummy substrates used for the continuous dummy processing before a leading product substrate is carried into the second processing module after the transfer container accommodating the product substrate is mounted on the container mounting part.

3. The substrate processing apparatus of claim 2, wherein the dummy substrate used in the second processing module is provided from the dummy substrate holder into the second processing module as a transfer destination.

4. The substrate processing apparatus of claim 3, wherein, before the dummy substrate is provided from the dummy substrate holder into the second processing module as the transfer destination, all dummy substrates provided from the dummy substrate holder for the continuous dummy processing are collected in the dummy substrate holder.

5. The substrate processing apparatus of claim 1, wherein the control part includes a selection part selecting one of a main mode in which a first processing is performed on the product substrate transferred into the first processing module after being taken out from the transfer container by the substrate transfer mechanism, while a second processing is performed on the product substrate transferred into the second processing module before or after the first processing, and a sub-mode in which the second processing module is used without using the first processing module.

6. The substrate processing apparatus of claim 1, wherein the control part includes a selection part selecting one of a mode in which, in the state where the continuous dummy processing continues, when the transfer container accommodating the product substrate to be processed in the second processing module is mounted on the container mounting part, the product substrate is carried into the second processing module and processed, while the continuous dummy processing continues, and a mode in which, in the state where the continuous dummy processing continues, when the transfer container accommodating the product substrate to be processed in the second processing module is mounted on the container mounting part, the product substrate is carried into the second processing module and processed, while the dummy substrate used for the continuous dummy processing is collected in the dummy substrate holder, whereby the continuous dummy processing is stopped during the process in the second processing module.

7. The substrate processing apparatus of claim 1, wherein the inside of the substrate transfer chamber and processing chambers of the processing modules are kept in a vacuum environment, and a load lock chamber is interposed between the container mounting part and the substrate transfer chamber.
